(19) United States
(12) Patent Application Publication
(10) Pub. No.: US 2016/0316573 A1
(43) Pub. Date: Oct. 27, 2016

(54) SOLDER MASK FIRST PROCESS

(71) Applicant: Dyi-Chung HU, Hsinchu (TW)

(72) Inventor: Dyi-Chung HU, Hsinchu (TW)

(21) Appl. No.: 15/074,484

(22) Filed: Mar. 18, 2016

Related U.S. Application Data
(60) Provisional application No. 62/151,228, filed on Apr. 22, 2015.

(51) Int. Cl. H05K 3/46; H05K 3/00

(52) U.S. Cl. CPC H05K 3/4644; H05K 3/007; H05K 3/0017; H05K 3/0073; H05K 2203/041

(57) ABSTRACT

A solder mask first process is disclosed, the solder mask first process comprising: preparing a temporary carrier, applying an adhesive layer on a top surface of the temporary carrier; applying a first dielectric layer on a top surface of the adhesive layer; forming build-up circuit on a top surface of the first dielectric layer; stripping the temporary carrier; etching the first dielectric layer to form a plurality of recesses, each recess reveal a bottom surface of a corresponding metal pad. Wherein the first dielectric layer functions as a solder mask.

### BACKGROUND

1. Technical Field

The present invention relates to a build-up circuit layer process, especially relates to a “solder mask first” process.

2. Description of Related Art

FIGS. 1A˜1B shows a prior art process.

FIG. 1A shows a prior art

FIG. 1A shows that U.S. Pat. No. 7,635,641 disclosed a build-up circuit layer 10. The build-up circuit layer 10 has a plurality of build-up circuits embedded therein. A plurality of metal pads 11 are formed on a bottom surface of the build-up circuit layer 10. Dielectric layers 14, 14′, 24, 24′ configured in the build-up circuit layer 10 for embedding partial of the circuitry.

FIG. 1B shows a layer of solder mask 12 is formed on a bottom surface of the circuit layer 10 in a later step. The solder mask 12 is then patterned and etched to form a plurality of recesses 13. A bottom surface of each metal pad 11 is revealed from a corresponding recess 13.

The prior art shows that the solder mask 12 is formed after the bottom metal pad 11 is formed. The prior art disclosed a “solder mask last” process. The disadvantage is that the bottom pads 11 does not coplanar ideally due to process deviation. The uneven bottom surfaces of the metal pad 11 causes uneven bottom among solder balls if solder balls are planted on each metal pad 11 in a later process. The uneven bottom among solder balls causes electrical contact problems in a later mounting process.

### BRIEF DESCRIPTION OF THE DRAWINGS

FIGS. 1A˜1B shows a prior art process.

FIGS. 2A˜2H show a fabricating process for a first embodiment according to the present invention.

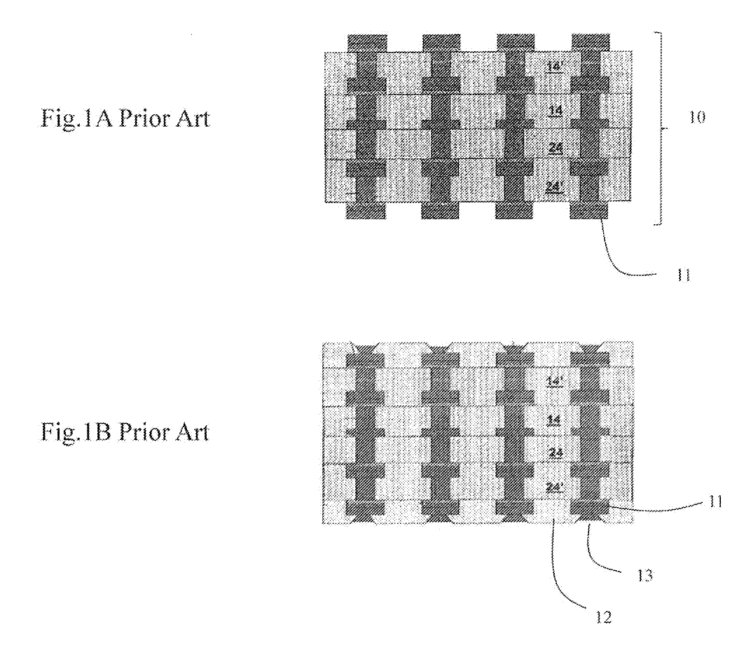

### DETAILED DESCRIPTION OF THE INVENTION

A first dielectric layer D1 formed on a temporary carrier 20. A build-up circuit layer 20 is configured on a top surface of the first dielectric layer D1. The first dielectric layer D1 functions as a solder mask in a later step of the process according to the present invention.

An advantage according to the present invention is that the first dielectric layer D1 provides a coplanar surface for the metal pads 25 of the first metal M1 which is configured on a bottom of the build-up circuit layer 20. Therefore, the metal pads 25 of the first metal M1 have a coplanar surface on bottom surface. The flat bottom of the metal pads 25 is favorable for obtaining a better electrical contact in a later process.

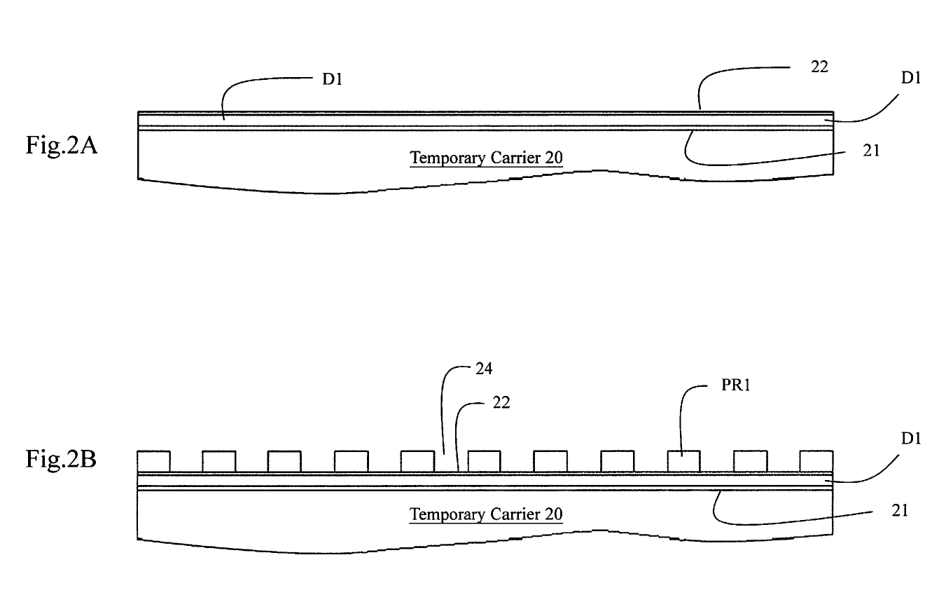

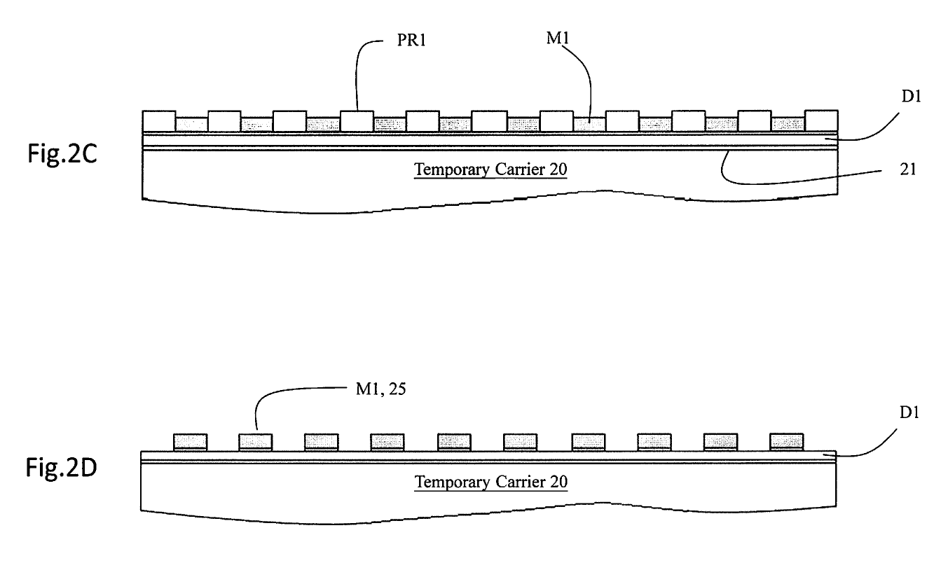

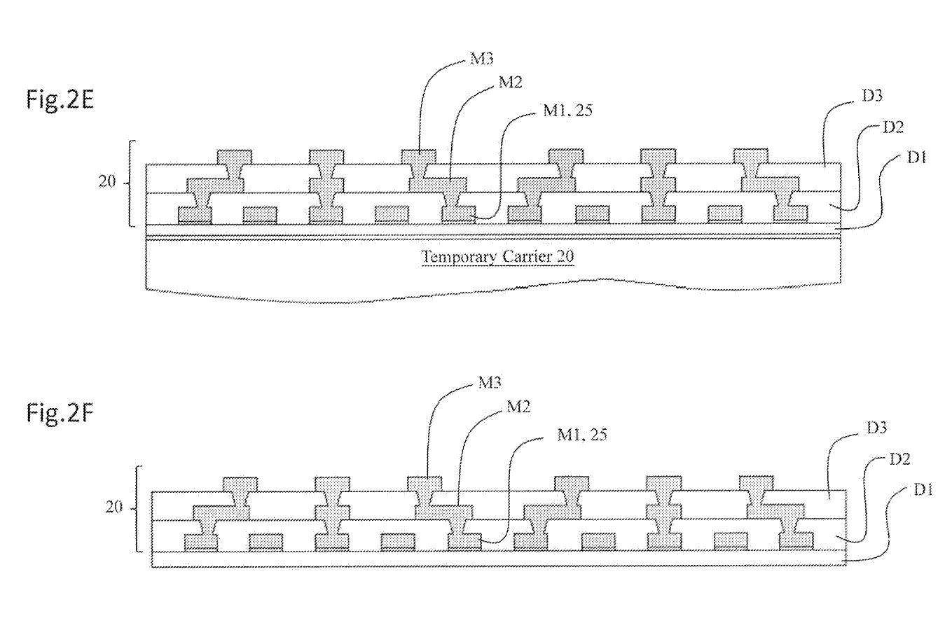

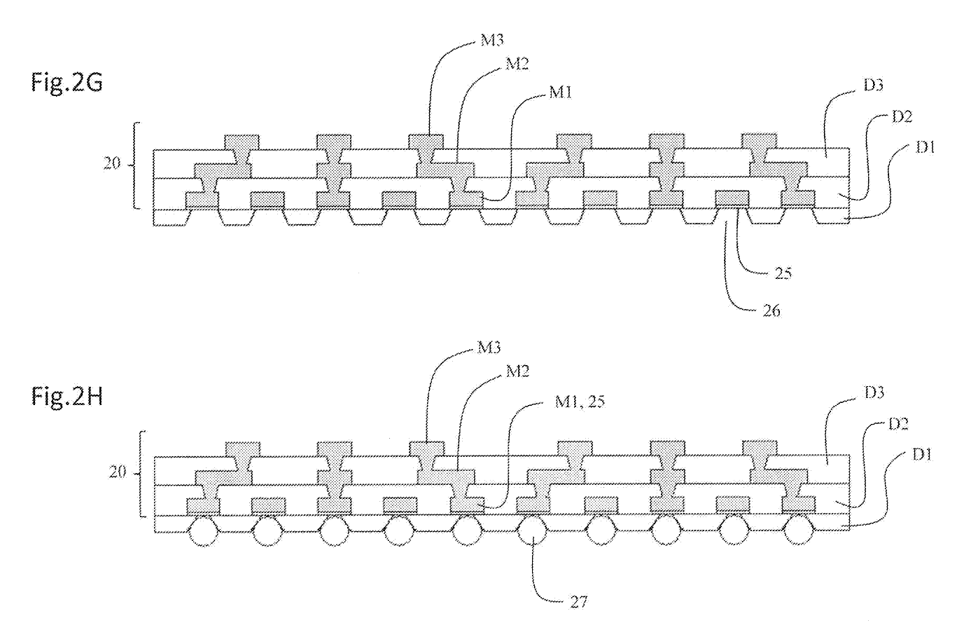

FIGS. 2A˜2H show a fabricating process for a first embodiment according to the present invention.

FIG. 2A shows:
preparing a temporary carrier 20;
applying an adhesive layer 21 on a top surface of the temporary carrier 20;
applying a first dielectric layer D1 on a top surface of the adhesive layer 21;
applying a first seed layer 22 on a top surface of the first dielectric layer D1.

FIG. 2B shows:
applying a first photoresist PRI on a top surface of the seed layer 22;
patterning the first photoresist PRI to form a plurality of recesses 24.

FIG. 2C shows:
plating to form a first metal M1 in each recess 24; a plurality of metal pads 25 are formed in the first metal M1.

FIG. 2D shows:
stripping the first photoresist PRI and stripping the seed layer 22 between the metal pads 25.

FIG. 2E shows:
a second metal M2, a third metal M3, a second dielectric layer D2, and a third dielectric layer D3 are formed with similar processes on a top surface of the first metal M1. More layer of metals and dielectric layers can be made with similar processes.

FIG. 2F shows:
removing the temporary carrier 20 as well as the adhesive layer 21;

FIG. 2G shows:
etching the first dielectric layer D1 from bottom to form a plurality recesses 26, each recess reveals a bottom surface of a corresponding metal pad 25 of the first metal M1. A surface finish such as Organic Solderability Preservative (OSP), Electroless-Nickel-Electroless-Palladium-Immersion-Gold (ENEPIG) or equivalent can be applied on a bottom surface of each metal pad 25 as a protection to prevent the metal pad 25 from being oxidized, scratched, or contaminated etc.

FIG. 2H shows
planting a plurality of solder balls 27, each solder ball 27 is configured on a bottom surface of a corresponding metal pad 25 of the first metal M1.

The first dielectric layer D1 functions as a solder mask according the present invention.

While several embodiments have been described by way of example, it will be apparent to those skilled in the art that various modifications may be configured without departs from the spirit of the present invention. Such modifications are all within the scope of the present invention, as defined by the appended claims.

What is claimed is:

1. A solder mask first process, comprising:
preparing a temporary carrier, applying an adhesive layer on a top surface of the temporary carrier;
applying a first dielectric layer on a top surface of the adhesive layer;
forming build-up circuit on a top surface of the first dielectric layer; wherein a plurality of metal pads formed on a bottom of the build-up circuit layer;
stripping the temporary carrier; and
etching from bottom of the first dielectric layer to form a plurality of recesses, each recess reveals a bottom surface of a corresponding metal pad on a bottom surface of the build-up circuit layer.

2. A solder mask first process as claimed in claim 1, further comprising:
applying a protection material on a bottom surface of each metal pad.

3. A solder mask first process as claimed in claim 2, wherein the protection material is selected from a group consisting of OSP and ENEPIG.

4. A solder mask first process as claimed in claim 1, further comprising a plurality of solder balls, each solder ball is configured on a bottom surface of a corresponding metal pad.
